(19) United States
(12) Patent Application Publication
(10) Pub. No.: US 2024/0363319 A1
(43) Pub. Date: Oct. 31, 2024

(54) PLASMA MONITORING DEVICE

(71) Applicant: Dah Young Vacuum Equipment Co., Ltd., TAICHUNG CITY (TW)

(72) Inventors: Tzu-Hou Chan, TAICHUNG CITY (TW); Ching-Yen Lin, TAICHUNG CITY (TW); Chu-Liang Ho, TAICHUNG CITY (TW); Ping-Yen Hsieh, TAICHUNG CITY (TW); Ying-Hung Chen, TAICHUNG CITY (TW)

(73) Assignee: Dah Young Vacuum Equipment Co., Ltd., TAICHUNG CITY (TW)

(21) Appl. No.: 18/354,609

(22) Filed: Jul. 18, 2023

(30) Foreign Application Priority Data
Apr. 27, 2023 (TW) 112115684

(51) Int. Cl. H01J 37/32

(52) U.S. Cl. CPC H01J 37/32972; H01J 37/32981

(57) ABSTRACT

A plasma monitoring device including at least one first cathode, at least one second cathode, a first collimator group, a first mass flow controller group, and a plasma emission monitor is disclosed. The first cathode has a first target and provides a first plasma. The second cathode has a second target and provides a second plasma. The first collimator group is disposed corresponding to the first cathode to detect a first spectrum of the first plasma. The first mass flow controller group provides gas to the first cathode and the second cathode through a first gas supply pipe group and a second gas supply pipe group. The plasma emission monitor adjusts a flow rate of the gas provided by the first mass flow controller group according to the first spectrum of the first plasma. The first target and the second target are the same. A total number of collimator groups is less than a total number of cathodes.

### CROSS-REFERENCE TO RELATED APPLICATION

This application claims the priority benefit of Taiwan application serial no. 112115684, filed on Apr. 27, 2023. The entirety of the above-mentioned patent application is hereby incorporated by reference herein and made a part of this specification.

### BACKGROUND

### Technical Field

The invention relates to a plasma monitoring device, and more particularly, to a plasma monitoring device that may save cost and reduce system complexity.

### Description of Related Art

At present, a standard plasma monitoring device at least includes one cathode, one group of optical collimator group corresponding to the number of the cathodes, and one group of mass flow controller (MFC) group with the same number as the optical collimator group, and one group of gas supply pipe group with the same number as the optical collimator group. Each group of the optical collimator group, the mass flow controller group, and the gas supply pipe group may have 2-4 optical collimators, 2-4 mass flow controllers and 2-4 gas supply pipes depending on a length of the cathode.

However, a present mass-production type sputtering equipment is often a batch type that uses 4 cathodes to increase a production speed, so that the plasma monitoring device used for the mass-production type sputtering equipment needs at least 4 groups of optical collimator groups (8-16 optical collimators) corresponding to the number of the cathodes, and 4 groups of mass flow controller groups (8-16 mass flow controllers) with the same number as the optical collimator groups and 4 groups of gas supply pipe groups (8-16 gas supply pipes) with the same number as the optical collimator groups. As a result, the user cannot bear the huge cost required for the plasma monitoring device.

### SUMMARY

The invention provides a plasma monitoring device, which has effects of saving costs and reducing system complexity.

A plasma monitoring device in the invention includes at least one first cathode, at least one second cathode, a first collimator group, a first mass flow controller group, and a plasma emission monitor. The first cathode has a first target and provides a first plasma. The second cathode has a second target and provides a second plasma. The first collimator group is disposed corresponding to the first cathode to detect a first plasma spectrum of the first plasma. The first mass flow controller group provides gas to the first cathode and the second cathode through a first gas supply pipe group and a second gas supply pipe group respectively. The plasma emission monitor adjusts a flow rate of the gas provided by the first mass flow controller group according to the first plasma spectrum of the first plasma. The first target and the second target are the same. A total number of collimator groups is less than a total number of cathodes.

In an embodiment of the invention, the total number of the collimator groups is equal to 1, and the total number of the cathodes is greater than or equal to 2.

In an embodiment of the invention, a total number of mass flow controller groups is less than the total number of the cathodes.

In an embodiment of the invention, the total number of the mass flow controller groups is equal to 1, and the total number of the cathodes is greater than or equal to 2.

In an embodiment of the invention, a first light intensity of the first plasma of the first cathode is substantially the same as a second light intensity of the second plasma of the second cathode.

In an embodiment of the invention, a difference between a first light intensity of the first plasma of the first cathode and a second light intensity of the second plasma of the second cathode is within 10%.

In an embodiment of the invention, the plasma monitoring device further includes at least one third cathode, a second collimator group, and a second mass flow controller group. The third cathode has a third target and provides a third plasma. The second collimator group is disposed corresponding to the third cathode to detect a third light intensity of the third plasma of the third cathode. The second mass flow controller group provides another gas to the third cathode through a third gas supply pipe group. The first target is different from the third target. The total number of the collimator groups is less than the total number of the cathodes.

In an embodiment of the invention, the total number of the collimator groups is equal to 2, and the total number of the cathodes is greater than or equal to 3.

In an embodiment of the invention, a total number of mass flow controller groups is less than the total number of the cathodes.

In an embodiment of the invention, the total number of the mass flow controller groups is equal to 2, and the total number of the cathodes is greater than or equal to 3.

Based on the above, in the plasma monitoring device of an embodiment of the invention, since the first light intensity of the first plasma of the first cathode may still be substantially the same as the second light intensity of the second plasma of the second cathode under the situation that the total number of the collimator groups or mass flow controller groups is reduced, the plasma monitoring device according to an embodiment of the invention may be used to replace a general standard plasma monitoring device, so as to achieve effects of saving costs or reducing system complexity.

In order for the aforementioned features and advantages of the invention to be more comprehensible, several embodiments accompanied with drawings are described in detail as follows.

### BRIEF DESCRIPTION OF THE DRAWINGS

FIG. 1 is a schematic diagram of a structure of a plasma monitoring device according to an embodiment of the invention.

FIG. 2 is a schematic diagram of a structure of a plasma monitoring device according to another embodiment of the invention.

FIG. 3A is a schematic diagram of a structure of a plasma monitoring device in a control group.

FIG. 3B is a schematic diagram of a structure of a plasma monitoring device in an experimental group.

FIG. 4 is a plasma spectrum of two cathodes when a light intensity of a plasma is preset at 5000 photon counts in the control group.

FIG. 5 is a plasma spectrum of two cathodes when a light intensity of a plasma is preset at 5000 photon counts in the experimental group.

FIG. 6 is a plasma spectrum of two cathodes when a light intensity of a plasma is preset at multiple photon counts in the control group.

FIG. 7 is a plasma spectrum of two cathodes when a light intensity of a plasma is preset at multiple photon counts in the experimental group.

### DESCRIPTION OF THE EMBODIMENTS

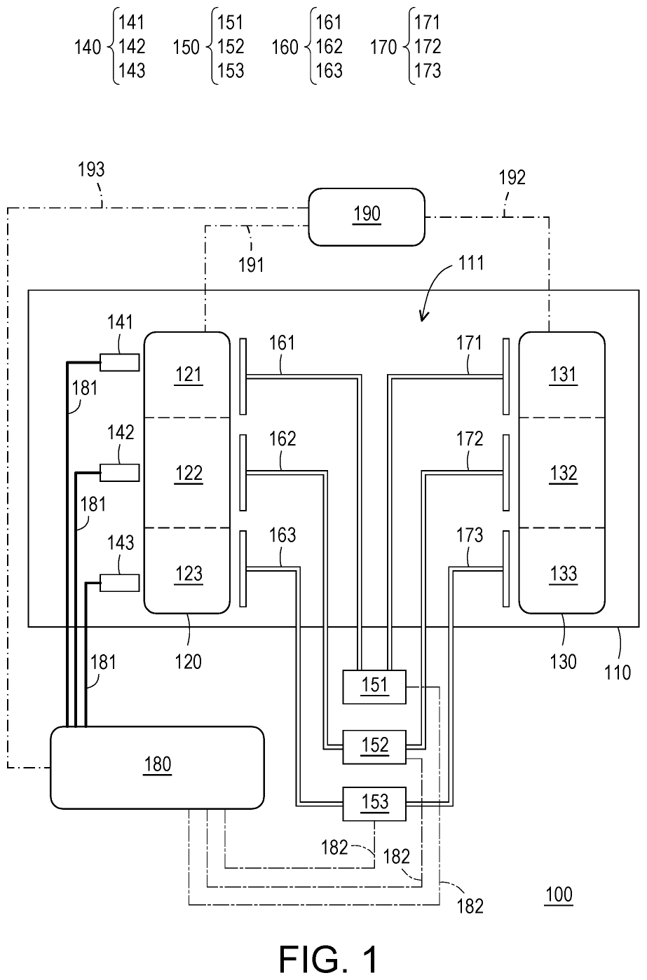

FIG. 1 is a schematic diagram of a structure of a plasma monitoring device according to an embodiment of the invention. Referring to FIG. 1, a plasma monitoring device 100 of the embodiment includes a chamber 110, at least one first cathode 120 (one seat is schematically taken as an example in FIG. 1, but the invention is not limited thereto), at least one second cathode 130 (one seat is schematically taken as an example in FIG. 1, but the invention is not limited thereto), a first collimator group 140, a first mass flow controller group 150, a first gas supply pipe group 160, a second gas supply pipe group 170, a plasma emission monitor 180 and a power supply 190. Where, the first cathode 120, the second cathode 130, the first collimator group 140, the first gas supply pipe group 160 and the second gas supply pipe group 170 are arranged in the chamber 110, and the first mass controller group 150, the plasma emission monitor 180 and the power supply 190 are disposed outside the chamber 110, but the invention is not limited thereto. In the embodiment, the plasma monitoring device 100 may be used, for example, to detect, diagnose and adjust the state of the plasma in a vacuum plasma process, so as to achieve the effect of stabilizing the plasma and overall uniformity.

Specifically, in the embodiment, the chamber 110 has an accommodating space 111. A vacuum system (not shown) composed of various vacuum pumps may create vacuum for the accommodating space 111 so that the accommodating space 111 may be in a vacuum state.

The first cathode 120 is disposed on a left side of the accommodating space 111. The first cathode 120 may sequentially include an upper region 121, a middle region 122 and a lower region 123 from top to bottom. The first cathode 120 has a first target and may provide a first plasma. In the embodiment, the first target may be, for example, titanium, and the first plasma may be, for example, titanium atoms or free titanium ions, but the invention is not limited thereto.

The second cathode 130 is disposed on a right side of the accommodating space 111. The second cathode 130 may sequentially include an upper region 131, a middle region 132 and a lower region 133 from top to bottom. The second cathode 130 has a second target and may provide a second plasma. Where, the second target may be the same as the first target, but the invention is not limited thereto. In the embodiment, the second target may be, for example, titanium, and the second plasma may be, for example, titanium atoms or free titanium ions, but the invention is not limited thereto. In the embodiment, a total number of cathodes (i.e., the first cathode 120 and the second cathode 130) is equal to 2 (seats), but the invention is not limited thereto.

The first collimator group 140 is disposed on a left side of the first cathode 120, but the invention is not limited thereto. The first collimator group 140 may be disposed corresponding to the first cathode 120 to detect a first plasma spectrum of the first plasma provided by the first cathode 120. In the embodiment, the first collimator group 140 may include a collimator 141, a collimator 142 and a collimator 143, but the invention is not limited thereto. The collimator 141 is disposed corresponding to the upper region 121 of the first cathode 120 to detect the first plasma spectrum of the first plasma in the upper region 121. The collimator 142 is disposed corresponding to the middle region 122 of the first cathode 120 to detect the first plasma spectrum of the first plasma in the middle region 122. The collimator 143 is disposed corresponding to the lower region 123 of the first cathode 120 to detect the first plasma spectrum of the first plasma in the lower region 123. For example, when the first target of the first cathode 120 is titanium, the first collimator group 140 may be used to detect a light intensity (i.e., photon counts) of the free titanium ions at a wavelength of 453.6 nm. In some embodiments, the first collimator group may also detect light intensities of other wavelengths according to characteristics of other atoms or ions to be detected. In addition, in the embodiment, a total number of the collimator group (i.e., the first collimator group 140) is equal to 1, but the invention is not limited thereto.

The first mass flow controller group 150 is arranged on one side outside the chamber 110, the first gas supply pipe group 160 is arranged on a right side of the first cathode 120, and the second gas supply pipe group 170 is arranged on a left side of the second cathode 130, but the invention is not limited thereto. The first mass flow controller group 150 may be respectively connected to the first gas supply tube group 160 and the second gas supply tube group 170, and the first mass flow controller group 150 may respectively provide gas to the first cathode 120 and the second cathode 130 through the first gas supply tube group 160 and the second gas supply tube group 170. In detail, in the embodiment, the first mass flow controller group 150 may include a mass flow controller 151, a mass flow controller 152 and a mass flow controller 153, and the first gas supply pipe group 160 may include a gas supply pipe 161, a gas supply pipe 162 and a gas supply pipe 163, and the second gas supply pipe group 170 may include a gas supply pipe 171, a gas supply pipe 172 and a gas supply pipe 173, but the invention is not limited thereto. Where, the mass flow controller 151 is respectively connected to the gas supply pipe 161 and the gas supply pipe 171, the mass flow controller 152 is respectively connected to the gas supply pipe 162 and the gas supply pipe 172, and the mass flow controller 153 is respectively connected to the gas supply pipe 163 and the gas supply pipe 173. The gas supply pipe 161, the gas supply pipe 162 and the gas supply pipe 163 are respectively disposed corresponding to the upper region 121, the middle region 122 and the lower region 123 of the first cathode 120. The gas supply pipe 171, the gas supply pipe 172 and the gas supply pipe 173 are respectively disposed corresponding to the upper region 131, the middle region 132 and the lower region 133 of the second cathode 130. Also, in the embodiment, the gas may include oxygen (O₂), but the invention is not limited thereto. In the embodiment, a total number of the mass flow controller group (i.e., the first mass flow controller group 150) may be equal to 1, but the invention is not limited thereto.

A plasma emission monitor (PEM) 180 is disposed on one side outside the chamber 110. The plasma emission monitor 180 may adjust a flow rate of the gas provided by the first mass flow controller group 150 according to the first plasma spectrum. In detail, the plasma emission monitor 180 may include optical fibers 181 and signal lines 182. The optical fibers 181 may be connected to the first collimator group 140, and the signal lines 182 may be connected to the first mass flow controller group 150. In the embodiment, the plasma emission monitor 180 may first receive the first plasma spectrum detected by the first collimator group 140 through the optical fibers 181, and then analyze a signal of the first plasma spectrum (for example, a light intensity of the plasma), and adjust the flow rate of the gas provided by the first mass flow controller group 150 through the signal lines 182 according to an analysis result of the first plasma spectrum, so as to make the plasma to be evenly distributed by controlling an atmosphere concentration, thereby stabilizing the fabrication process. In the embodiment, since the first cathode 120 and the second cathode 130 share a same set of mass flow controller group (i.e., the first mass flow controller group 150), the flow rate of the gas provided to the first cathode 120 by the first mass flow controller group 150 may be substantially the same as the flow rate of the gas provided to the second cathode 130, and the flow rate of the gas received by the first cathode 120 may be substantially the same as the flow rate of the gas received by the second cathode 130.

For example, when the light intensity presented by the plasma spectrum of the upper region 121 of the first cathode 120 is less than the light intensities presented by the plasma spectrums of the middle region 122 and the lower region 123, the plasma emission monitor 180 may respectively control the flow rates of the gases provided by the mass flow controller 151, the mass flow controller 152 and the mass flow controller 153 through the different signal lines 182, so that the light intensities presented by the plasma spectrums of the upper region 121, the middle region 122 and the lower region 123 of the first cathode 120 may be substantially the same, and the light intensities presented by the plasma spectrums of the upper region 131, the middle region 132 and the lower region 133 of the second cathode 130 may also be substantially the same. When the light intensity presented by the plasma spectrum in the upper region 121 (or the middle region 122 or the lower region 123) of the first cathode 120 is different from a preset value, the plasma emission monitor 180 may control the flow rate of the gas provided by the mass flow controller 151 (or the mass flow controller 152 or the mass flow controller 153) through the corresponding signal line 182, so that the light intensity presented by the plasma spectrum of the upper region 121 (or the middle region 122 or the lower region 123) of the first cathode 120 may be substantially the same as the preset value, and the light intensity presented by the plasma spectrum of the upper region 131 (or the middle region 132 or the lower region 133) of the second cathode 130 may also be substantially the same as the preset value. Therefore, in the plasma monitoring device 100 of the embodiment, the first light intensity of the first plasma of the first cathode 120 may be, for example, substantially the same as the second light intensity of the second plasma of the second cathode 130, but the invention is not limited thereto. In some embodiments, a difference between the first light intensity of the first plasma of the first cathode 120 and the second light intensity of the second plasma of the second cathode 130 may be, for example, within 10%, but the invention is not limited thereto.

The power supply 190 may include a power output cable 191, a power output cable 192 and a power signal line 193. Where, the power output cable 191 may be connected to the first cathode 120, the power output cable 192 may be connected to the second cathode 130, and the power signal line 193 may be connected to the plasma emission monitor 180. A form of the power supply 190 may be direct current, intermediate frequency, radio frequency or high power magnetic control pulse, but the invention is not limited thereto.

In the embodiment, the first target is the same as the second target, a total number of the collimator group (i.e. the first collimator group 140) may be less than a total number of the cathodes (i.e. the first cathode 120 and the second cathode 130), a total number of the mass flow controller group (i.e. the first mass flow controller group 150) may be less than the total number of the cathodes (i.e. the first cathode 120 and the second cathode 130), and the total number of the collimator group (i.e. the first collimator group 140) may be equal to the total number of the mass flow controller group (i.e., the first mass flow controller group 150).

Although the total number of the cathodes (i.e., the first cathode 120 and the second cathode 130) in the embodiment is 2 (seats), the invention does not limit the total number of the cathodes. In some embodiments, the total number of the cathodes may also be greater than or equal to 3.

Although the number of collimators in the first collimator group 140 of the embodiment is 3, the invention does not limit the number of the collimators in the collimator group. In some embodiments, the number of the collimators in the collimator group may also be 1, 2 or more than 3. In some embodiments, the number of the collimators in the collimator group may also be determined according to a length of the cathode.

Although the number of the mass flow controllers in the first mass flow controller group 150 in the embodiment is three, the invention does not limit the number of the mass flow controllers in the mass flow controller group. In some embodiments, the number of the mass flow controllers in the mass flow controller group may also be 1, 2 or more than 3.

In addition, compared to the general plasma monitoring device with 2 cathodes that requires 2 groups of collimator groups and 2 groups of mass flow controller groups, the plasma monitoring device 100 of the embodiment only needs to be provided with 1 group of the collimator group and 1 group of the mass flow controller group, so that the plasma monitoring device 100 of the embodiment has the effects of reducing system complexity and saving cost. In addition, in some embodiments, even if the total number of the cathodes is greater than 2, as long as the targets of all of the cathodes are the same, only one group of the first collimator group and one group of the first mass flow controller group 150 are required.

Other embodiments will be listed below for illustration. It should be noticed that reference numbers of the components and a part of contents of the aforementioned embodiment are also used in the following embodiment, where the same reference numbers denote the same or like components, and descriptions of the same technical contents are omitted. The aforementioned embodiment may be referred for descriptions of the omitted parts, and detailed descriptions thereof are not repeated in the following embodiment.

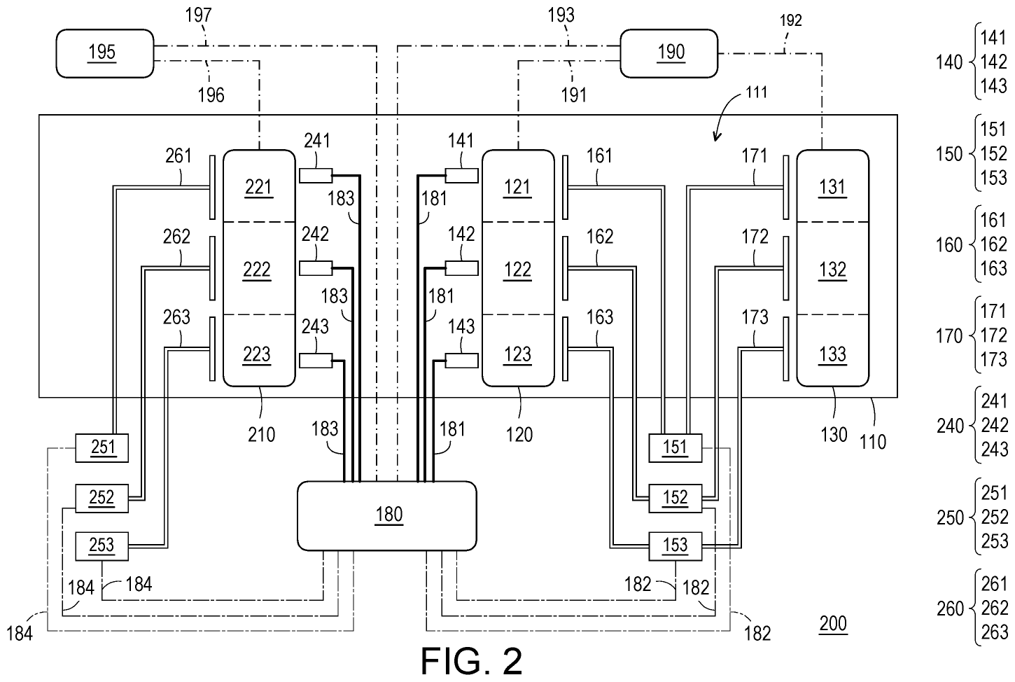

FIG. 2 is a schematic diagram of a structure of a plasma monitoring device according to another embodiment of the invention. Referring to FIG. 1 and FIG. 2 at the same time, a plasma monitoring device 200 of the embodiment is similar to the plasma monitoring device 100 of FIG. 1, and a main difference there between is that the plasma monitoring device 200 of the embodiment further includes a third cathode 210, a second collimator group 240, a second mass flow controller group 250, a third gas supply tube group 260 and a power supply 195, and a third target of the third cathode 210 may be different from the first target and the second target.

Referring to FIG. 2, in the plasma monitoring device 200 of the embodiment, the third cathode 210 and the second collimator group 240 are arranged in the chamber 110, and the second mass flow controller group 250 is arranged outside the chamber 110, but the invention is not limited thereto.

Specifically, the third cathode 210 is disposed on a left side of the accommodating space 111, and the first cathode 120 is disposed between the third cathode 210 and the second cathode 130, but the invention is not limited thereto. The third cathode 210 may sequentially include an upper region 211, a middle region 212 and a lower region 213 from top to bottom. The third cathode 210 has a third target and may provide a third plasma. Where, the third target may be different from the first target and the second target, but the invention is not limited thereto. In the embodiment, the third target may be, for example, chromium, and the third plasma may be, for example, chromium atoms, chromium molecules or free chromium ions, but the invention is not limited thereto. In the embodiment, a total number of the cathodes (i.e., the first cathode 120, the second cathode 130 and the third cathode 210) is equal to 3 (seats), but the invention is not limited thereto.

The second collimator group 240 is disposed on a right side of the third cathode 210, but the invention is not limited thereto. The second collimator group 240 may be disposed corresponding to the third cathode 210 to detect a third plasma spectrum of the third plasma provided by the third cathode 210. In the embodiment, the second collimator group 240 may include a collimator 241, a collimator 242 and a collimator 243, but the invention is not limited thereto. The collimator 241 is disposed corresponding to the upper region 211 of the third cathode 210 to detect the third plasma spectrum of the third plasma of the upper region 211. The collimator 242 is disposed corresponding to the middle region 212 of the third cathode 210 to detect the third plasma spectrum of the third plasma of the middle region 212. The collimator 243 is disposed corresponding to the lower region 213 of the third cathode 210 to detect the third plasma spectrum of the third plasma of the lower region 213. In the embodiment, a total number of collimator groups (i.e., the first collimator group 140 and the second collimator group 240) is equal to 2, but the invention is not limited thereto.

The second mass flow controller group 250 is disposed on one side outside the chamber 110, and the third gas supply pipe group 260 is disposed on the left side of the third cathode 210, but the invention is not limited thereto. The second mass flow controller group 250 may be connected to the third gas supply pipe group 260, and the second mass flow controller group 250 may provide gas to the third cathode 210 through the third gas supply pipe group 260. In detail, in the embodiment, the second mass flow controller group 250 may include a mass flow controller 251, a mass flow controller 252, and a mass flow controller 253, and the third gas supply pipe group 260 may include a gas supply pipe 261, a gas supply pipe 262 and a gas supply pipe 263, but the invention is not limited thereto. Where, the mass flow controller 251, the mass flow controller 252 and the mass flow controller 253 are respectively connected to the gas supply pipe 261, the gas supply pipe 262 and the gas supply pipe 263. The gas supply pipe 261, the gas supply pipe 262 and the gas supply pipe 263 are respectively arranged corresponding to the upper region 211, the middle region 212 and the lower region 213 of the third cathode 210. Moreover, in the embodiment, the gas may include oxygen, but the invention is not limited thereto. In the embodiment, a total number of the mass flow controller groups (i.e., the first mass flow controller group 150 and the second mass flow controller group 250) may be equal to 2, but the invention is not limited thereto.

The power supply 195 may include a power output cable 196 and a power signal line 197. Where, the power output cable 196 may be connected to the third cathode 210, and the power signal line 197 may be connected to the plasma emission monitor 180. The form of the power supply 195 may be direct current, intermediate frequency, radio frequency or high power magnetic control pulse, but the invention is not limited thereto.

In the plasma monitoring device 200 of the embodiment, the plasma emission monitor 180 may further include optical fibers 183 and signal lines 184. The optical fibers 183 may be connected to the second collimator group 240, and the signal lines 184 may be connected to the second mass flow controller group 250.

In the plasma monitoring device 200 of the embodiment, the first target is the same as the second target and the first target is different from the third target, and the total number of the collimator groups (i.e., the first collimator group 140 and the second collimator group 240) may be less than the total number of the cathodes (i.e. the first cathode 120, the second cathode 130 and the third cathode 210), the total number of the mass flow controller groups (i.e. the first mass flow controller group 150 and the second mass flow controller group 250) may be less than the total number of the cathodes (i.e. the first cathode 120, the second cathode 130 and the third cathode 210), and the total number of the collimator groups (i.e. the first collimator group 140 and the second collimator group 240) may be equal to the total number of the mass flow controller groups (i.e., the first mass flow controller group 150 and the second mass flow controller group 250).

In addition, unlike the plasma monitoring device 100 in FIG. 1, since the plasma monitoring device 200 of the embodiment has another target, an additional group of collimator group and mass flow controller groups is required. Namely, different from a general standard plasma monitoring device, in the plasma monitoring device designed in the embodiment, the total number of the collimator groups and the total number of the mass flow controller groups are adjusted based on a number of types (or type number) of the targets. Where, the total number of the collimator groups may be the same as the number of types (or type number) of the targets, and the total number of the mass flow controller groups may also be the same as the number of types (or type number) of the targets.

Hereinafter, the plasma monitoring device of the above-mentioned embodiment will be described in detail by means of an experimental example. However, the following experimental example is not intended to limit the invention.

[Experimental example]: confirm whether light intensities of plasmas provided by two cathodes in a plasma monitoring device of an experimental group are substantially the same or a difference therebetween is within 10%.

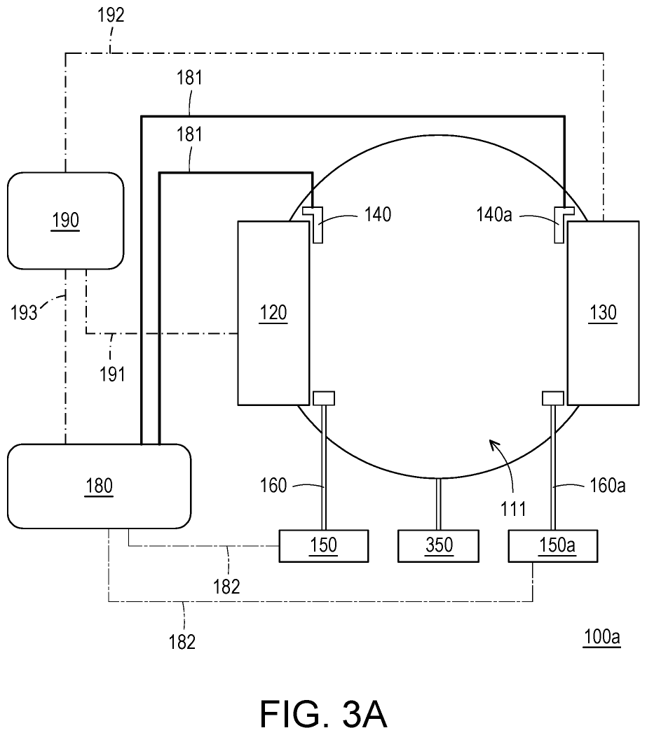

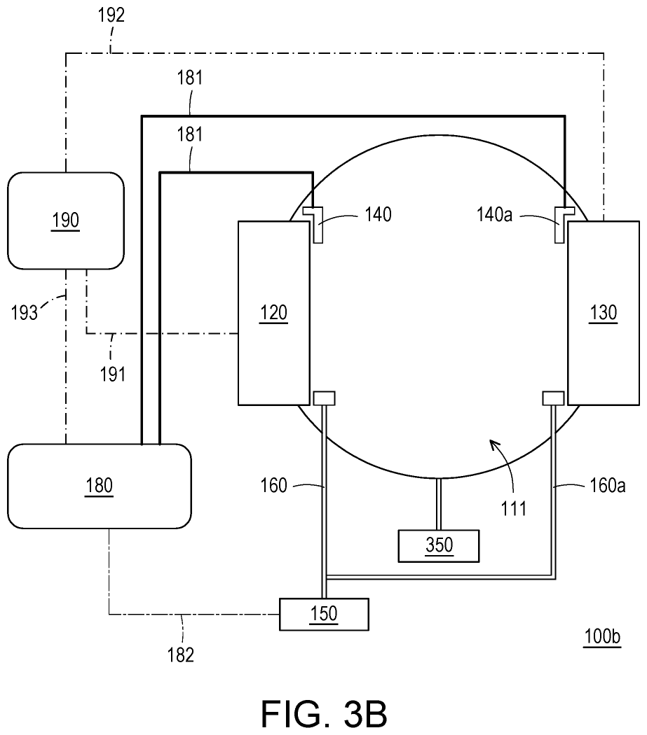

First, referring to FIG. 3A, FIG. 3A is a schematic diagram of a structure of a plasma monitoring device in a control group. A plasma monitoring device 100a of the control group includes at least two cathodes containing titanium (i.e., the first cathode 120 and the second cathode 130), and two groups of collimator groups (i.e., the first collimator group 140 and a first collimator group 140a) corresponding to the number of the cathodes, two groups of mass flow controller groups (i.e., the first mass flow controller group 150 and a first mass flow controller group 150a) with the same number as that of the collimator groups, two groups of gas supply pipe groups (i.e., the first gas supply pipe group 160 and a first gas supply pipe group 160a) with the same number as that of the collimator groups, and a mass flow controller 350 used for supplying argon (Ar). Namely, the plasma monitoring device 100a of the control group may be regarded as a general standard plasma monitoring device.

Then, referring to FIG. 3B, FIG. 3B is a schematic diagram of a structure of a plasma monitoring device in an experimental group. A plasma monitoring device 100b of the experimental group includes at least two cathodes containing titanium (i.e. the first cathode 120 and the second cathode 130), one group of collimator group (i.e. the first collimator group 140), one group of mass flow controller group (i.e. the first mass flow controller group 150), two groups of gas supply pipe groups (i.e. the first gas supply pipe group 160 and the first gas supply pipe group 160a) and the mass flow controller 350 for supplying argon (Ar). Namely, compared with the plasma monitoring device 100a of the control group, the plasma monitoring device 100b of the experimental group is lack of the first collimator group 140a and the first mass flow controller group 150a, and the plasma monitoring device 100b of the experimental group may be regarded as a plasma monitoring device according to an embodiment of the invention. In addition, although FIG. 3B illustrates the first collimator group 140a, the first collimator group 140a here is only used to detect and confirm whether the second light intensity of the second plasma of the second cathode 130 is substantially the same as the first light intensity of the first plasma of the first target set 120, or a difference therebetween is within 10%, namely, a detection result of the first collimator group 140a will not be used as a reference for adjusting a flow rate of oxygen by the plasma monitoring device 100b, and the first collimator group 140a is not a conventional configuration of an embodiment of the invention and may be omitted.

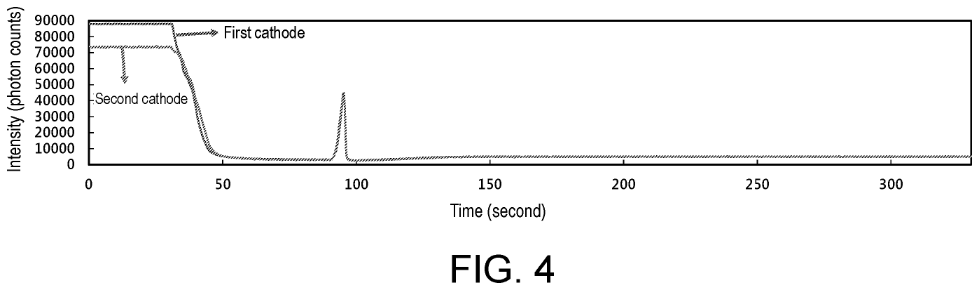

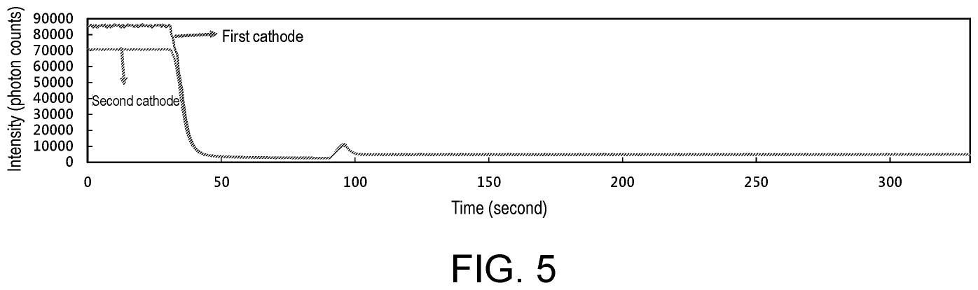

Then, referring to FIG. 4 and FIG. 5 at a same time, FIG. 4 is a plasma spectrum of the two cathodes when the light intensity of the plasma is preset at 5000 photon counts in the control group, and FIG. 5 is a plasma spectrum of the two cathodes when the light intensity of the plasma is preset at 5000 photon counts in the experimental group.

FIG. 4 and FIG. 5 are detecting results of plasma spectrums (i.e., free titanium ions) of the plasmas provided by the two cathodes at a wavelength of 453.6 nm. Where, the 0-30^{th} seconds are the plasma spectrum of plasma when oxygen is not provided, the 30^{th}-90^{th} seconds are the plasma spectrum of plasma when oxygen of a fixed flow rate is provided, and the 90-390^{th} seconds are the plasma spectrum when the flow rate of oxygen is adjusted according to the preset value (5000 photon counts) and a real-time monitoring result. Moreover, the light intensities (photon counts) (cts) of the plasma detected at the specific time in FIG. 4 are recorded in Table 1 below, and the light intensities (photon counts) of the plasma detected at the specific time in FIG. 5 are reported in Table 2 below.

TABLE 1

| | 30^{th} sec. | 55^{th} sec. | 90^{th} sec. | 150^{th} sec. | 210^{th} sec. | 270^{th} sec. | 330^{th} sec. |
|---|---|---|---|---|---|---|---|
| First cathode | 87891 cts | 4326 cts | 3057 cts | 5125 cts | 5080 cts | 4980 cts | 4997 cts |
| Second cathode | 73766 cts | 4187 cts | 2927 cts | 5108 cts | 4797 cts | 4947 cts | 5059 cts |

TABLE 2

| | 30^{th} sec. | 55^{th} sec. | 90^{th} sec. | 150^{th} sec. | 210^{th} sec. | 270^{th} sec. | 330^{th} sec. |
|---|---|---|---|---|---|---|---|
| First cathode | 85454 cts | 3414 cts | 2846 cts | 5044 cts | 4858 cts | 4990 cts | 4981 cts |
| Second cathode | 70638 cts | 3095 cts | 2495 cts | 4719 cts | 4683 cts | 4742 cts | 4881 cts |

From the results of Table 1 and Table 2, it is known that in the 30-90^{th} seconds of the control group or the experimental group, the light intensity of the plasma is gradually decreased along with time by providing oxygen with a fixed flow rate, and it is unable to maintain a fixed photon count. In the 90-390^{th} seconds of the control group, two groups of collimator groups are used to respectively monitor two cathodes, and two groups of mass flow controller groups are used to respectively adjust the flow rate of oxygen provided to the corresponding cathode according to the monitoring result of the corresponding cathode, so that the light intensities of the plasmas of the first cathode and the second cathode may be substantially maintained at the preset 5000 photon counts. In the 90-390^{th} seconds of the experimental group, one group of collimator group is used to monitor the first cathode, and one group of mass flow controller group is used to adjust flow rates of the oxygen supplied to the two cathodes according to a monitoring result of the first cathode, so that the light intensity of the plasma of the first cathode is substantially maintained at the preset 5000 photon counts, and the light intensity of the plasma of the second cathode is substantially maintained at about 4700-5000 photon counts. Therefore, the light intensities of the plasmas provided by the two cathodes in the plasma monitoring device of the experimental group may be substantially the same or the difference therebetween is within 10%. Therefore, the applicant believes that the plasma monitoring device of the experimental group may be used to replace the plasma monitoring device of the control group, so as to achieve effects of saving costs or reducing system complexity.

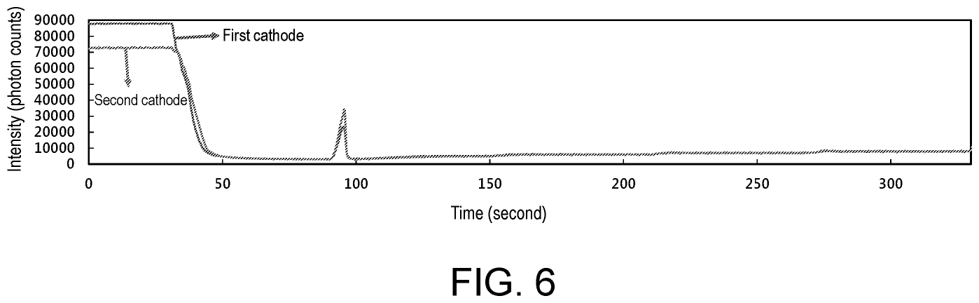

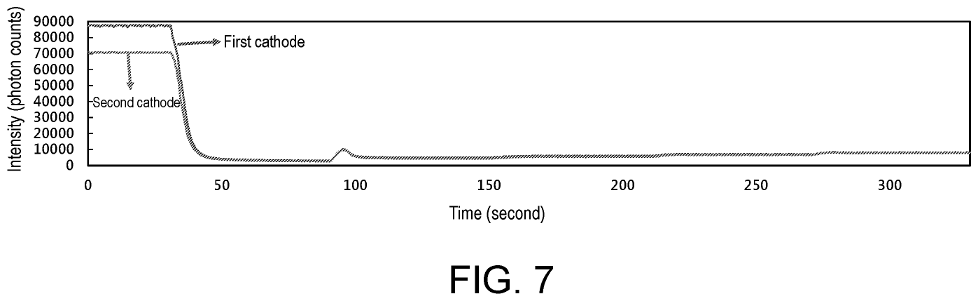

Then, referring to FIG. 6 and FIG. 7 at the same time, FIG. 6 is a plasma spectrum of the two cathodes when the light intensity of the plasma is preset at multiple photon counts in the control group, and FIG. 7 is a plasma spectrum of the two cathodes when the light intensity of the plasma is preset at multiple photon counts in the experimental group.

FIG. 6 and FIG. 7 are detecting results of plasma spectrums (i.e., free titanium ions) of the plasmas provided by the two cathodes at a wavelength of 453.6 nm. Where, the 0-30^{th} seconds are the plasma spectrum of plasma when oxygen is not provided, the 30^{th}-90^{th} seconds are the plasma spectrum of plasma when oxygen of a fixed flow rate is provided, the 90-150^{th} seconds are the plasma spectrum when the flow rate of oxygen is adjusted according to the preset value (5000 photon counts) and a real-time monitoring result, the 150-210^{th} seconds are the plasma spectrum when the flow rate of oxygen is adjusted according to the preset value (6000 photon counts) and the real-time monitoring result, the 210-270^{th} seconds are the plasma spectrum when the flow rate of oxygen is adjusted according to the preset value (7000 photon counts) and the real-time monitoring result, and the 270-330^{th} seconds are the plasma spectrum when the flow rate of oxygen is adjusted according to the preset value (8000 photon counts) and the real-time monitoring result. Moreover, the light intensities (photon counts) of the plasma detected at the specific time in FIG. 6 are recorded in Table 3 below, and the light intensities (photon counts) of the plasma detected at the specific time in FIG. 7 are reported in Table 4 below.

TABLE 3

| | 30^{th} sec. | 55^{th} sec. | 90^{th} sec. | 150^{th} sec. | 210^{th} sec. | 270^{th} sec. | 330^{th} sec. |
|---|---|---|---|---|---|---|---|
| First cathode | 87904 cts | 4087 cts | 3175 cts | 4936 cts | 5879 cts | 7154 cts | 8166 cts |
| Second cathode | 72597 cts | 4010 cts | 3026 cts | 4815 cts | 5872 cts | 7091 cts | 8043 cts |

TABLE 4

| | 30^{th} sec. | 55^{th} sec. | 90^{th} sec. | 150^{th} sec. | 210^{th} sec. | 270^{th} sec. | 330^{th} sec. |
|---|---|---|---|---|---|---|---|
| First cathode | 86964 cts | 3722 cts | 3108 cts | 4852 cts | 6098 cts | 7060 cts | 8096 cts |
| Second cathode | 70760 cts | 3288 cts | 2545 cts | 4313 cts | 5537 cts | 6731 cts | 7934 cts |

From the results of Table 3 and Table 4, it is known that in the 30-90^{th} seconds of the control group or the experimental group, the light intensity of the plasma is gradually decreased along with time by providing oxygen with a fixed flow rate, and it is unable to maintain a fixed photon count. In the 90-150^{th} seconds, the 150-210^{th} seconds, the 210-270^{th} seconds and the 270-330^{th} seconds of the control group, two groups of collimator groups are used to respectively monitor two cathodes, and two groups of mass flow controller groups are used to respectively adjust the flow rate of oxygen provided to the corresponding cathode according to the monitoring result of the corresponding cathode, so that the light intensities of the plasmas of the first cathode and the second cathode may be substantially maintained at the preset photon counts. In the 90-150^{th} seconds, the 150-210^{th} seconds, the 210-270^{th} seconds and the 270-330^{th} seconds of the experimental group, one group of collimator group is used to monitor the first cathode, and one group of mass flow controller group is used to adjust flow rates of the oxygen supplied to the two cathodes according to a monitoring result of the first cathode, so that the light intensity of the plasma of the first cathode is substantially maintained at the preset photon counts, and the light intensity of the plasma of the second cathode is also substantially maintained at the preset photon counts. Therefore, the light intensities of the plasmas provided by the two cathodes in the plasma monitoring device of the experimental group may be substantially the same or the difference therebetween is within 10%. Therefore, the applicant believes that the plasma monitoring device of the experimental group may be used to replace the plasma monitoring device of the control group, so as to achieve effects of saving costs or reducing system complexity.

In summary, in the plasma monitoring device of an embodiment of the invention, since the first light intensity of the first plasma of the first cathode may still be substantially the same as the second light intensity of the second plasma of the second cathode under the situation that the total number of the collimator groups or mass flow controller groups is reduced, the plasma monitoring device according to an embodiment of the invention may be used to replace a general standard plasma monitoring device, so as to achieve effects of saving costs or reducing system complexity.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. A plasma monitoring device, comprising:
at least one first cathode having a first target and providing a first plasma;
at least one second cathode having a second target and providing a second plasma;
a first collimator group disposed corresponding to the first cathode to detect a first plasma spectrum of the first plasma;
a first mass flow controller group providing gas to the first cathode and the second cathode through a first gas supply pipe group and a second gas supply pipe group respectively; and
a plasma emission monitor adjusting a flow rate of the gas provided by the first mass flow controller group according to the first plasma spectrum of the first plasma,
wherein the first target and the second target are the same, and a total number of collimator groups is less than a total number of cathodes.

2. The plasma monitoring device according to claim 1, wherein the total number of the collimator groups is equal to 1, and the total number of the cathodes is greater than or equal to 2.

3. The plasma monitoring device according to claim 1, wherein a total number of mass flow controller groups is less than the total number of the cathodes.

4. The plasma monitoring device according to claim 3, wherein the total number of the mass flow controller groups is equal to 1, and the total number of the cathodes is greater than or equal to 2.

5. The plasma monitoring device according to claim 1, wherein a first light intensity of the first plasma of the first cathode is substantially the same as a second light intensity of the second plasma of the second cathode.

6. The plasma monitoring device according to claim 1, wherein a difference between a first light intensity of the first plasma of the first cathode and a second light intensity of the second plasma of the second cathode is within 10%.

7. The plasma monitoring device according to claim 1, further comprising:
at least one third cathode having a third target and providing a third plasma;
a second collimator group, disposed corresponding to the third cathode to detect a third light intensity of the third plasma of the third cathode; and
a second mass flow controller group providing another gas to the third cathode through a third gas supply pipe group,
wherein the first target is different from the third target, and the total number of the collimator groups is less than the total number of the cathodes.

8. The plasma monitoring device according to claim 7, wherein the total number of the collimator groups is equal to 2, and the total number of the cathodes is greater than or equal to 3.

9. The plasma monitoring device according to claim 7, wherein a total number of mass flow controller groups is less than the total number of the cathodes.

10. The plasma monitoring device according to claim 9, wherein the total number of the mass flow controller groups is equal to 2, and the total number of the cathodes is greater than or equal to 3.
